(19) United States
(12) Patent Application Publication
(10) Pub. No.: US 2009/0065902 A1
(43) Pub. Date: Mar. 12, 2009

(54) METHOD OF FORMING A SEMICONDUCTOR DIE HAVING A SLOPED EDGE FOR RECEIVING AN ELECTRICAL CONNECTOR

(76) Inventors: Cheemen Yu, Madison, WI (US); Chih-Chin Liao, Changhua (TW); Hem Takiar, Fremont, CA (US)

Correspondence Address: VIERRA MAGEN/SANDISK CORPORATION, 575 MARKET STREET, SUITE 2500, SAN FRANCISCO, CA, 94105, US

(21) Appl. No.: 11/853,428

(22) Filed: Sep. 11, 2007

(51) Int. Cl. H01L 29/06; H01L 21/304; H01L 21/56

(52) U.S. Cl. 257/620; 438/109; 438/460; 257/E29.022; 257/E21.238; 257/E21.502

(57) ABSTRACT

A method of forming a low profile semiconductor package, and a semiconductor package formed thereby, is disclosed. The semiconductor die is formed with one or more sloped edges on which electrically conductive traces may be deposited to allow the semiconductor die to be coupled to another die and/or a substrate on which the die is mounted. Depositing the electrical traces directly on the surface and sloped edge of the die allows the die to be electrically coupled without bond wires, thereby allowing a reduction in the overall thickness of the package.

### BACKGROUND OF THE INVENTION

1. Field of the Invention

Embodiments of the present invention relate to a low profile semiconductor device and method of fabricating same.

2. Description of the Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While a wide variety of packaging configurations are known, flash memory storage cards may in general be fabricated as system-in-a-package (SiP) or multichip modules (MCM), where a plurality of die are mounted on a substrate. The substrate may in general include a rigid, dielectric base having a conductive layer etched on one or both sides. Electrical connections are formed between the die and the conductive layer(s), and the conductive layer(s) provide an electric lead structure for connection of the die to a host device. Once electrical connections between the die and substrate are made, the assembly is then typically encased in a molding compound to provide a protective package.

A cross-section of a conventional semiconductor package 20 (without molding compound) is shown in prior art FIGS. 1-3. Typical packages include a plurality of semiconductor die 22 affixed to a substrate 24. Two die are shown, but more than two may be provided. Once affixed, the die 22 may be wire bonded to the substrate via wire bonds 26. It is known to layer semiconductor die on top of each other either with an offset or in a stacked configuration. In an offset configuration, shown in FIG. 1, a die is stacked on top of another die so that the bond pads of the lower die are left exposed. An offset configuration provides an advantage of convenient access of the bond pads on each of the semiconductor die. However, offset configurations allow connection off of only one side of at least the bottom die. The offset also requires a greater footprint on the substrate, where space is at a premium.

In stacked configurations, such as that shown in FIGS. 2 and 3, two or more semiconductor die are stacked directly on top of each other, thereby taking up less footprint on the substrate as compared to an offset configuration. However, in a stacked configuration, space must be provided between adjacent semiconductor die for the bond wires 26. In addition to the height of the bond wires 26 themselves, additional space must be left above the bond wires, as contact of the bond wires 26 of one die with the next die above may result in an electrical short. As shown in FIG. 2, it is known to provide an insulative spacer 30 to separate the die and electrically isolate the upper die from the wire bonds 26. As shown in FIG. 3, instead of a spacer, it is also known to space the upper die from the wire bonds by burying the wire bonds within an adhesive layer 32 between the respective die. Such configurations are shown for example in U.S. Pat. No. 6,388,313 to Lee et al., entitled, “Multi-Chip Module,” and U.S. Pat. No. 7,037,756 to Jiang et al., entitled, “Stacked Microelectronic Devices and Methods of Fabricating Same.”

Stacked configurations of the prior art alleviate the problem of single-sided connectivity and footprint. However, there is an ever-present drive to increase storage capacity within memory modules. One method of increasing storage capacity is to increase the number of memory die used within the package. In portable memory packages, the number of die which may be used is limited by the thickness of the package. There is accordingly a keen interest in decreasing the thickness of the contents of a package while maintaining or even increasing memory density. The packages 20 shown in FIGS. 2-3 require a spacer layer 30 or adhesive layer 32 so as to ensure that the wire bond loops remain spaced from, and do not contact, the underside of the next adjacent semiconductor die during fabrication. This additional thickness becomes even more of a problem in packages having more than two stacked die and multiple layers of spacers or adhesive. The package 20 of FIG. 1 allows die to be stacked directly atop each other, but the wire bonds 26 still add height to the package, and the offset requires additional footprint in the package.

### SUMMARY OF THE INVENTION

An embodiment of the present invention relates to a method of forming low profile semiconductor packages and a semiconductor package formed thereby. In embodiments, the semiconductor die is formed with one or more sloped edges on which electrically conductive traces may be deposited to allow the semiconductor die to be coupled to another die and/or a substrate on which the die is mounted. In embodiments, when the semiconductor die are singulated from a wafer, the die are cut with a saw or laser that is angled with respect to the surface of the wafer to create at least one sloped edge on the semiconductor die. The sloped edge may either be positively or negatively sloped.

Once a die is singulated, it may be mounted on another component, which may either be a second semiconductor die or a substrate such as a printed circuit board. Where the second component is a substrate, the die and substrate may be electrically coupled to each other by forming electrically conductive traces which extend from a contact pad on the die, down a positively sloped edge and to a bond pad on the substrate. By providing a positively sloped edge, a trace deposition apparatus positioned above the die and substrate is able to deposit the material forming conductive traces directly onto the positively sloped edge as the apparatus moves between the respective bond pads. One or more semiconductor die, each having at least one positively sloped edge, may be mounted on and electrically coupled to a substrate using this process.

In embodiments, the electrical traces may be formed by a digital printing process which lays down a plurality of discrete but overlapping dots that form a continuous trace between the respective bond pads. Such digital printing techniques are able to accurately and repeatably lay down extremely thin and precise electrical traces. The electrical traces may be formed by processes other than digital printing in alternative embodiments.

Forming electrical traces along sloped edges of one or more semiconductor die results in a low profile semiconductor package in which a plurality of semiconductor die may be electrically coupled to a substrate without having to provide wire bonds between each die and the substrate. In particular, forming electrical traces directly on the surfaces of the die omits the vertical space required for wire bonding in conventional semiconductor packages. In addition to preventing the possibility of electrical short, omitting the wire bonds, and the accompanying space required for the wire bonds, allows a significant reduction in height and/or footprint of the finished semiconductor package. The thickness of the package may be only nominally greater than the thickness of the substrate and the semiconductor die used in the package.

### DESCRIPTION OF THE DRAWINGS

FIG. 1 is a side view of a prior art semiconductor package without molding compound showing a plurality of die stacked on a substrate in an offset configuration.

FIG. 2 shows a side view of a conventional semiconductor package without molding compound with a plurality of die stacked and separated by a spacer.

FIG. 3 shows a side view of a conventional semiconductor package without molding compound with a plurality of die stacked and separated by an adhesive layer.

FIG. 4 is a top view of a semiconductor wafer for use in the present invention.

FIGS. 5 and 6 are top and edge views of a semiconductor die singulated with a sloped edge according to the embodiments of the present invention.

FIG. 7 is a flowchart of a method for fabricating a semiconductor package according to the present invention.

FIG. 8 is an enlarged edge view of a pair of adjacent semiconductor die singulated from each other to create positive and negative sloped edges on the adjacent semiconductor die.

FIG. 9 is an enlarged edge view of a pair of adjacent semiconductor die singulated to create a pair of positively sloped edges on the adjacent semiconductor die.

FIGS. 10 and 11 are top and edge views of a semiconductor die according to the present invention mounted on a substrate.

FIG. 12 is a top view of a semiconductor die electrically coupled to a substrate according to an embodiment of the present invention.

FIGS. 13A and 13B are a pair of edge views of a semiconductor die showing electrical traces being formed between bond pads of a die and substrate according to an embodiment of the present invention.

FIG. 14 is an edge view of a semiconductor die electrically coupled to a substrate with an insulating layer provided on the positively sloped edge of the semiconductor die according to the embodiments of the present invention.

FIGS. 15 and 16 are top and edge views of an embodiment of the present invention including a pair of semiconductor die having sloped edges mounted on a substrate.

FIGS. 17 and 18 are top and edge views of an embodiment of the present invention including a pair of semiconductor die having sloped edges electrically coupled to a substrate.

FIGS. 19 and 20 are top and edge views of a further embodiment of the present invention during fabrication showing a first die mounted and electrically coupled to a substrate.

FIGS. 21 and 22 are top and edge views of the embodiment of FIGS. 19 and 20 during fabrication showing a first die mounted and electrically coupled to a substrate and a second die mounted to the first die.

FIGS. 23 and 24 are top and edge views of the embodiment of FIGS. 19 and 20 showing the first and second die mounted and electrically coupled to a substrate.

FIG. 25 is an edge view of a finished semiconductor package according to an embodiment of the present invention.

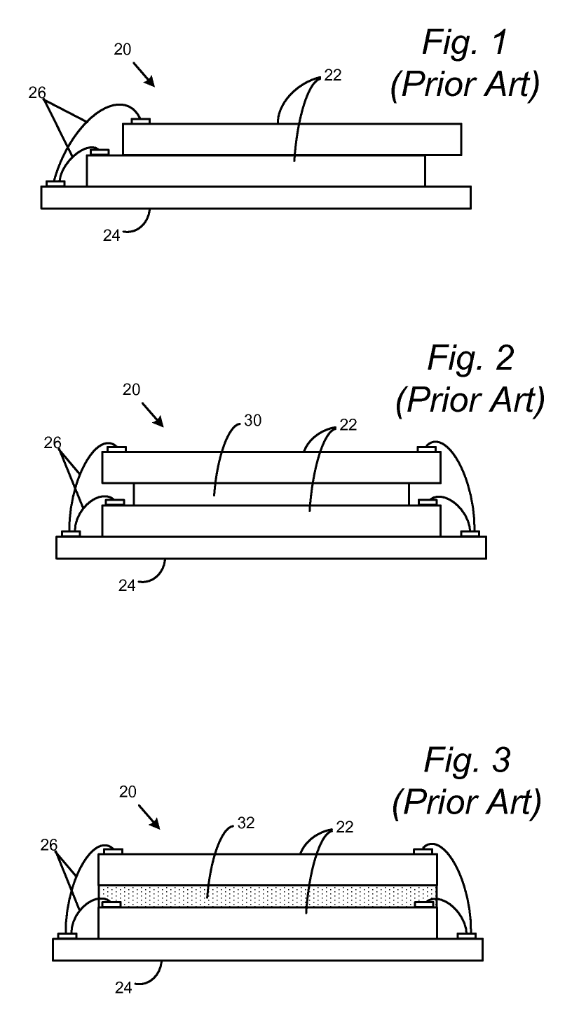

### DETAILED DESCRIPTION

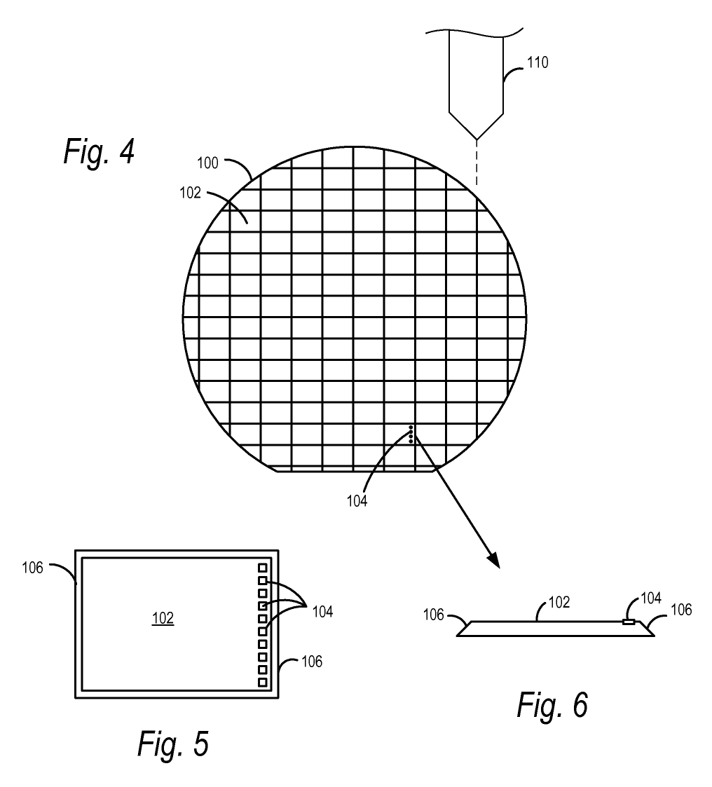

Embodiments will now be described with reference to FIGS. 4-25, which relate to a low profile semiconductor package. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

FIG. 4 shows a top view of a semiconductor wafer 100 for batch processing a plurality of semiconductor die 102 (one of which is labeled in FIG. 4). Each die 102 may be formed with bond pads 104 as shown for example in the enlarged view of die 102 in FIGS. 5 and 6. Bond pads 104 are used to electrically couple the semiconductor die 102 to another semiconductor die, or to a printed circuit board, leadframe or other substrate as explained hereinafter. While bond pads 104 are shown along a single edge of die 102, it is understood that the bond pads 104 may be formed along two opposed or adjacent edges, three edges or all four edges of each die 102 in alternative embodiments.

The die 102 may be formed on wafer 100 by known processes such as film deposition, photolithography, patterning, and diffusion of impurities. Die bond pads 104 may be formed by stud bumping, gold bumping, or any other known process for forming conductive pads on a semiconductor die. Such processes are often employed in forming a flip-chip semiconductor die. These processes include but are not limited to plating, evaporation, screen printing, or various deposition processes. In embodiments, die bond pads 104 may be over-plated with a metal, such as for example copper, to raise the height of the pads 104 above the surface of wafer 100. A backgrind process may be performed on wafer 100 as is known in the art to thin the die 102 to the desired thickness.

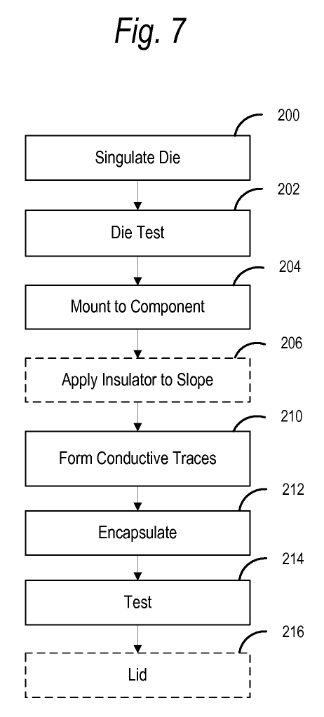

Referring now to the flowchart of FIG. 7, after the individual die and bond pads have been formed on wafer 100, the die 102 may be singulated from the wafer 100 in step 200 and as shown in FIGS. 5 and 6. In accordance with an aspect of the present invention, when a semiconductor die 102 is singulated from wafer 100, one or more edges of the die may be cut at an oblique angle with respect to a surface of the die 102. Conventionally, when semiconductor die are singulated from a wafer, the edges are cut along a plane at a substantially perpendicular angle to a surface of the wafer. However, in accordance with embodiments of the present invention, one or more edges of semiconductor die 102 may be cut along a cutting plane that is oblique (i.e., substantially not perpendicular) to the surface of semiconductor wafer 100 to form one or more sloped edges 106 on die 102. As explained in greater detail hereinafter, providing a sloped edge 106 as shown in FIGS. 5 and 6 enables an electrically conductive trace to be formed from a bond pad 104, down slope 106 and on to a component on which die 102 is mounted to electrically couple die 102 to the component.

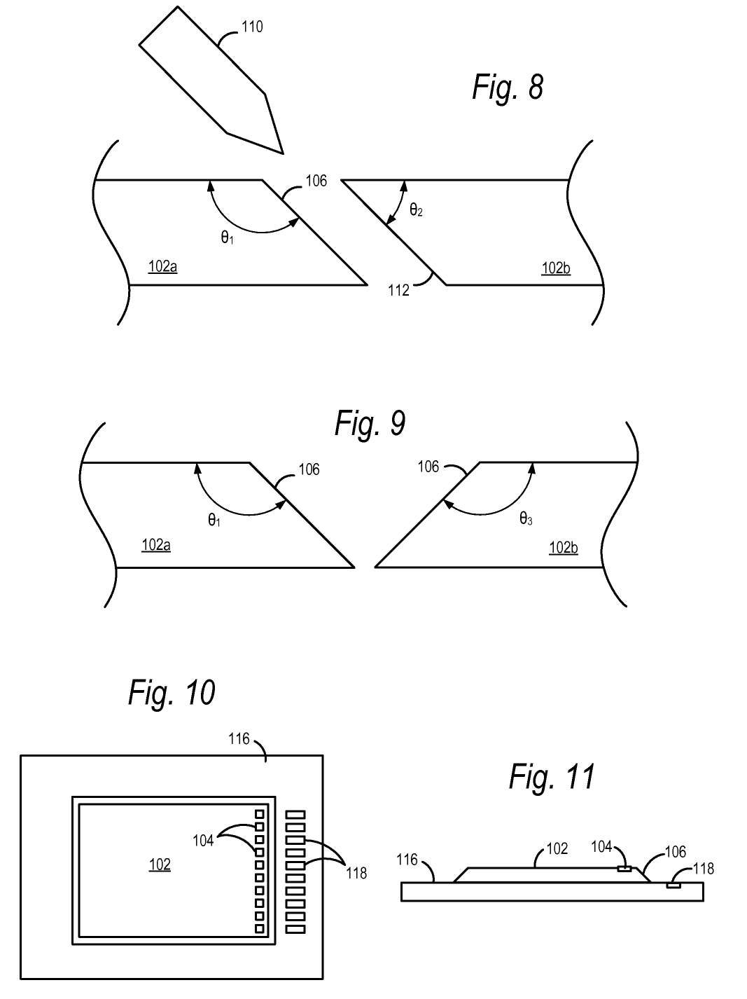

The die 102 may be singulated using a cutting instrument 110 shown symbolically in FIGS. 4 and 8. Cutting instrument 110 may be a known instrument for dicing semiconductor die from a wafer, such as for example a saw or laser. The saw or laser may be provided at the desired oblique angle with respect to the surface of the die, and then the cut is made. In further embodiments discussed hereinafter, die 102 may be singulated from wafer 100 using a chemical etching process.

In one embodiment shown in FIG. 8, cutting instrument 110 makes an angled cut through the wafer 100 producing a sloped edge 106 in die 102a having an angle θ₁ of greater than 90°. A sloped edge 106 having an angle greater than 90° is said to be a positively sloped edge, as it has a horizontal component on which a conductive trace may be deposited. In the embodiment shown in FIG. 8, the same cut which produces positively sloped edge 106 in die 102a may produce a corresponding negatively sloped edge 112 in adjacent die 102b. Negatively sloped edge 112 may have an angle θ₂ of less than 90° with respect to the die surface. In embodiments, negatively sloped edges 112 do not receive the conductive traces.

Referring still to FIG. 8, one or more cutting instruments 110 may make successive cuts horizontally across the face of wafer 100 so that each die 102 will have a first positively sloped edge 106 and a second negatively sloped edge 112 on the opposite edge of the die 102. The cutting instrument 110 may then proceed vertically across the wafer to complete the singulation of each die 102. The vertical cut may be perpendicular to the surface of the wafer to create semiconductor die 102 having a pair of sloped edges (one positive, one negative) and a pair of perpendicular edges. Alternatively, the vertical cut may also be performed at an angle with respect to the wafer surface to create semiconductor die 102 having a first pair of opposed sloped edges, and a second pair of opposed sloped edges.

In embodiments, cutting instrument 110 may be angled so as to create a positive slope having an angle θ₁ between the wafer surface and the sloped edge 106 of between 120° and 150°, and more particularly 1350. It is understood that the angle θ₁ may be greater than or lesser than the range set forth above. For example, θ₁ may be any angle greater than 90° having a sufficient horizontal component to allow an electrical trace to be deposited thereon, for example by digital printing as explained hereinafter. Similarly, the angle θ₁ may be greater than 150° in alternative embodiments. However, as the horizontal component of sloped edge 106 gets larger as θ₁ increases, space considerations within a semiconductor package may limit θ₁ from getting too large, though it is still feasible. In the embodiment of FIG. 8, the negatively sloped edge 112 may have an angle θ₂ which is complementary to angle θ₁.

In the embodiment described in respect to FIG. 8, a single cut creates a positively sloped edge 106 and a negatively sloped edge 112 in adjacent semiconductor die 102. However, in an alternative embodiment of the present invention, it is contemplated that a single cut between adjacent semiconductor die 102 may create two positively sloped edges 106. Such an embodiment is shown in FIG. 9. Those of skill in the art will appreciate a variety of methods for creating a pair of positively sloped edges 106 in adjacent semiconductor die. For example, a cutting blade 110 may be oriented substantially perpendicularly to the surface of the wafer 100, and have a pair of beveled cutting edges which form the pair of positively sloped edges 106 as the respective beveled edges cut into and through the wafer 100. As another example, cutting instrument 110 may make a first cut creating a positively sloped edge 106 in die 102a having an angle θ₁. The cutting instrument may then rotate and make a second cut creating positively sloped edge 106 in semiconductor die 102b having an angle θ₃. The angles θ₁ and θ₃ may or may not be equal to each other. In a further embodiment, it is contemplated that a chemical etchant be applied to the surface of wafer 100 at the boundary between respective semiconductor die 102 on the wafer. The chemical etchant may etch through the wafer so as to create two positively sloped edges 106 as shown in FIG. 9. Other methods for creating positively sloped edges between adjacent semiconductor die 102 are contemplated.

Referring again to the flowchart of FIG. 7, once the die is singulated from wafer 100, the die may be tested in a known electrical and thermal stress test in a step 202. Thereafter, in a step 204, a die 102 may be mounted on a component 116 using a known die attach compound as shown in the top and edge views of FIGS. 10 and 11, respectively. As explained hereinafter, component 116 may be a second semiconductor die, or component 116 may be a substrate such as for example a printed circuit board, leadframe, or a tape automated bonding (“TAB”) tape.

FIGS. 10 and 11 illustrate an embodiment where component 116 is a substrate. The substrate 116 in this and other embodiments may for example be a printed circuit board including a core sandwiched between top and bottom conductive layers. The core may be various dielectric materials such as for example, polyimide laminates, epoxy resins including FR4 and FR5, bismaleimide triazine (BT), and the like. The conductive layers may be formed of copper or copper alloys, plated copper or plated copper alloys, Alloy 42 (42FE/58NI), copper plated steel or other metals or materials known for use on substrates.

The conductive layers may be etched into a conductance pattern as is known for communicating signals between the semiconductor die and an external device. A dummy pattern may also be provided in the conductive layers as is known to reduce mechanical stresses on the substrate otherwise resulting from uneven thermal expansion within the substrate. Substrate 116 may additionally include exposed metal portions forming bond pads 118. Where the finished semiconductor package is a land grid array (LGA) package, the conductance pattern on one of the conductive layers may further include contact fingers (not shown) for allowing communication between the semiconductor package and the host device within which the package is located. The bond pads 118 and/or contact fingers may be plated with one or more gold layers, for example in an electroplating process as is known in the art.

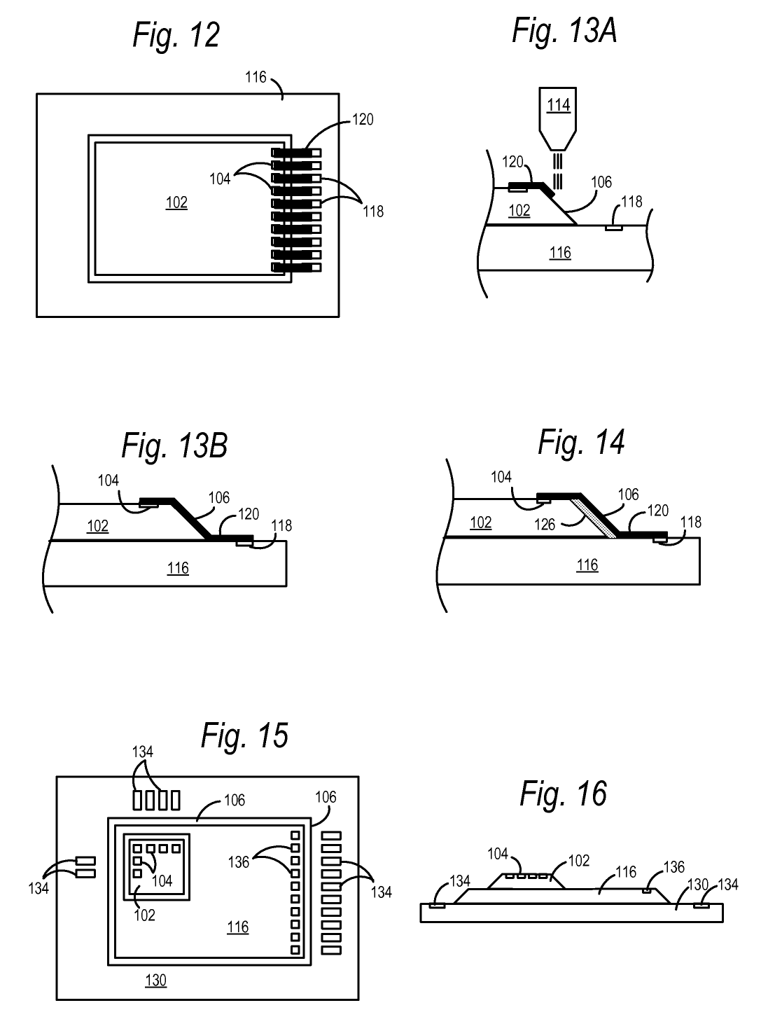

The bond pads 118 are provided to allow electrical coupling of the substrate 116 to the semiconductor die 102 in step 210 of the flowchart of FIG. 7. As seen in the top view of FIG. 12 and partial edge views of FIGS. 13A and 13B, electrically conductive traces 120 may be formed between respective bond pads 104 and 118 on die 102 and component 116. In particular, as shown in FIG. 13A, as die 102 is cut with a positively sloped edge 106, an apparatus 114 positioned above die 102 is able to deposit the material forming conductive traces 120 on the positively sloped edge as the apparatus moves (relative to die 102 and component 116) from the bond pad 104 to bond pad 118. In each of the embodiments shown in the figures, the number of bond pads and traces is by way of example only. Embodiments may include greater or lesser numbers of bond pads and traces. Moreover, some bond pads may not have a trace 120 affixed thereto and may go unused.

The electrically conductive traces 120 may be formed by a variety of processes. In one embodiment, electrical traces 120 may be formed by a digital printing process which lays down a plurality of discrete but overlapping dots of conductive material. In such an embodiment, the overlapping dots may form a continuous trace having a first end in contact with a die bond pad 104, and which extends down over positively sloped edge 106, terminating at a bond pad 118 on substrate 116.

A variety of known digital printing machines may be used to form traces 120, such as for example the Dimatix DMP-2800 series digital printer from Fujifilm Dimatix, Inc. of Santa Clara, Calif. Such digital printers deposit a discrete amount, or dots, of a conductive powder suspended within a liquid solvent. The liquid solvent evaporates leaving the conductor adhered to the surface on which it was deposited to accurately and repeatably lay down extremely thin and precise electrical traces. In an embodiment, each dot may have a diameter of between 5 and 30 microns, and more particularly between 10 and 20 microns. It is understood that the diameter of a dot in the digital printing process may be smaller or larger than that in alternative embodiments.

Traces 120 may be defined by a single line of overlapping dots. In alternative embodiments, two or more dots may be deposited side-by-side across a width of traces 120 to create traces 120 having larger widths. While the figures show traces 120 proceeding in straight lines from bond pads 104 to bond pads 118, it is understood that traces 120 may be digitally printed in any of a variety of patterns from a bond pad 104, down a positively sloped edge 106 to bond pad 118 in further embodiments.

While embodiments of the present invention use a digital printing process to generate conductive traces 120, it is understood that traces 120 may be formed by a variety of other processes in alternative embodiments of the present invention. For example, those of skill in the art would appreciate that traces 120 may be formed by deposition of a conductive film, for example by chemical vapor deposition or by electron beam physical vapor deposition. The film may be photolithographically patterned to define traces 120 in the desired trace pattern.

The top surface of die 102 may have an electrical insulator formed or otherwise provided thereon. However, when the die are singulated to create positively sloped edge 106, sloped edge 106 may not be insulated. Therefore, referring now to the flowchart of FIG. 7 and the partial edge view of FIG. 14, prior to forming the conductor traces of step 210, embodiments of the present invention include a step 206, where an insulator 126 is provided on sloped edge 106. Insulator 126 may be a variety of insulating materials, and may be formed on edge 106 by a variety of processes. One such process may be digital printing, as described above for forming traces 120. In such embodiments, the insulating material 126 may be formed only at locations where the traces 120 are to be formed. Alternatively, the insulating layer 126 may be laid down along the entire edge 106.

As indicated above, the component 116 may either be another semiconductor die or a substrate. In FIGS. 12-14 described above, component 116 is a substrate to which die 102 is coupled. FIGS. 15-18 illustrate an embodiment of the present invention where component 116 is a second semiconductor die. Referring initially to the top and edge views of FIGS. 15 and 16, respectively, the illustrated assembly may be configured by mounting a semiconductor die 116 onto a component 130. In embodiments, the component 130 is a substrate as described above, but it is contemplated that component 130 may be a further semiconductor die. Where component 130 is a substrate, substrate 130 may include bond pads 134 for coupling to die 116 and die 102 as explained below. Semiconductor die 116 may be formed with bond pads 136. In one embodiment, die 116 may be a flash memory die and die 102 may be a controller die, such as for example an ASIC. Die 116 may be mounted on substrate 130 using a known die attach compound, and then controller die 102 may be mounted atop die 116.

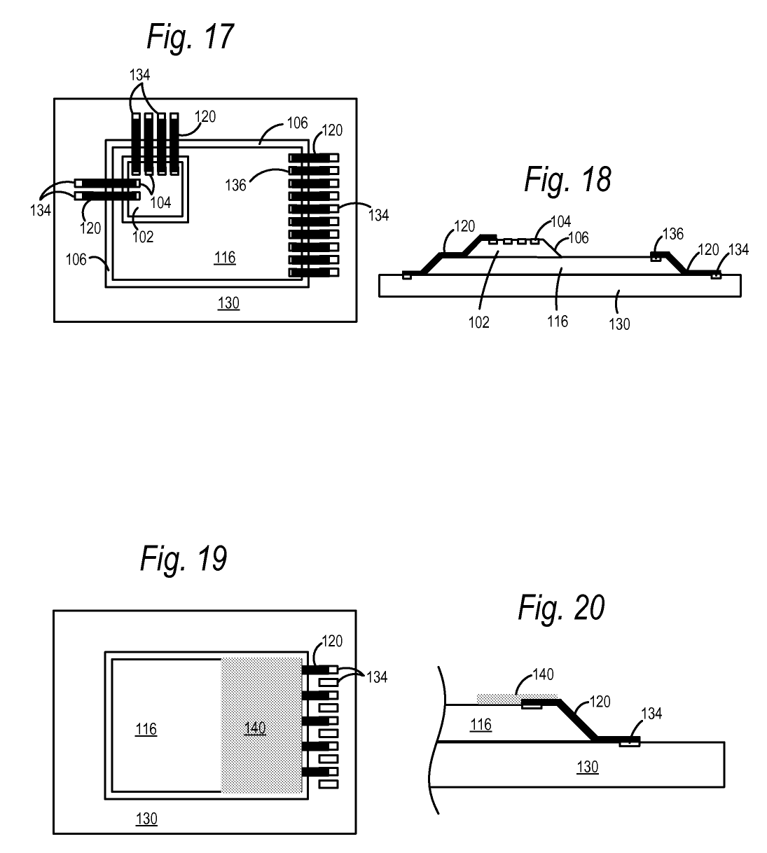

Referring now to the top and edge views of FIGS. 17 and 18, respectively, once die 102 and die 116 are mounted on substrate 130, the die 102 and 116 may next be electrically coupled to substrate 130 via electrically conductive traces 120 as described above. In particular, bond pads 136 of die 116 may be coupled to bond pads 134 of substrate 130 by forming electrical traces 120 from bond pads 136, down the adjacent positively sloped edge 106 and then to bond pads 134. Similarly, bond pads 104 of die 102 may be electrically coupled to bond pads 134 on substrate 130. In particular, as best seen in the edge view of FIG. 18, electrical traces 120 may be coupled to bond pad 104, down a positively sloped edge 106 on die 102, across a surface of die 116, down a positively sloped edge 106 of die 116, and then on to a surface of substrate 130 where the trace may be terminated at bond pads 134. Electrically conductive traces 120 extending between bond pads 104 and bond pads 134 may be laid down in a single deposition process, such as for example the digital printing process described above. In an alternative embodiment, die 102 may be coupled only to die 116. In such embodiments, all communication between die 102 and substrate 130 may take place via electrical connections through die 116.

In the embodiments of FIGS. 12 and 13, die 102 required only a single positively sloped edge 106, as traces 120 were formed between bond pads along a single edge of the die 102. In the embodiments shown in FIG. 17, die 116 would include a positively sloped edge 106 along at least three sides of the die. That is, die 116 would include a positively sloped edge 106 along the right edge (as seen in FIG. 17) to allow traces to be formed between bond pads 134 and 136. Die 116 would also include a positively sloped edge 106 along the top and left sides to allow traces to be formed between bond pads 104 on die 102 and bond pads 134 on substrate 130. Similarly, die 102 in the embodiment of FIG. 17 requires positively sloped edges along at least the left and top edges of die 102 (again, as seen in FIG. 17).

In the embodiment of FIGS. 15-18, one or more of the positively sloped edges may include an electrical insulator 126 as described above, which will be formed on one or more of the positively sloped edges by various methods such as for example digital printing or film deposition processes.

In the embodiments shown in FIGS. 15-18, die 102 has a smaller footprint than die 116, as may be the case where die 102 is an ASIC and die 116 is a memory die. In further embodiments, a pair of die 102 and 116 of substantially the same size may be coupled to a substrate using traces 120. Such an embodiment will now be described with reference to FIGS. 19-24. The embodiment of FIGS. 19-24 begins with the structure shown in FIGS. 12 and 13. Namely, a first semiconductor die has been mounted on and electrically coupled to a substrate via traces 120 as described above. FIG. 19 shows less electrical traces 120 than in FIG. 12, but it is understood that the number of traces may be the same, and additional bond pads may be provided in the embodiment of FIG. 19. As shown in FIGS. 19 and 20, an electrical insulator 140 could also be provided over traces 120 leading from die 116. The insulator 140 may cover the entire surface of the die, or the insulator may be deposited only over sections on a top surface of die 116 where traces 120 are formed. Although not shown, insulator 140 may also be deposited beneath and/or above traces 120 on positively sloped edge 106 of die 116.

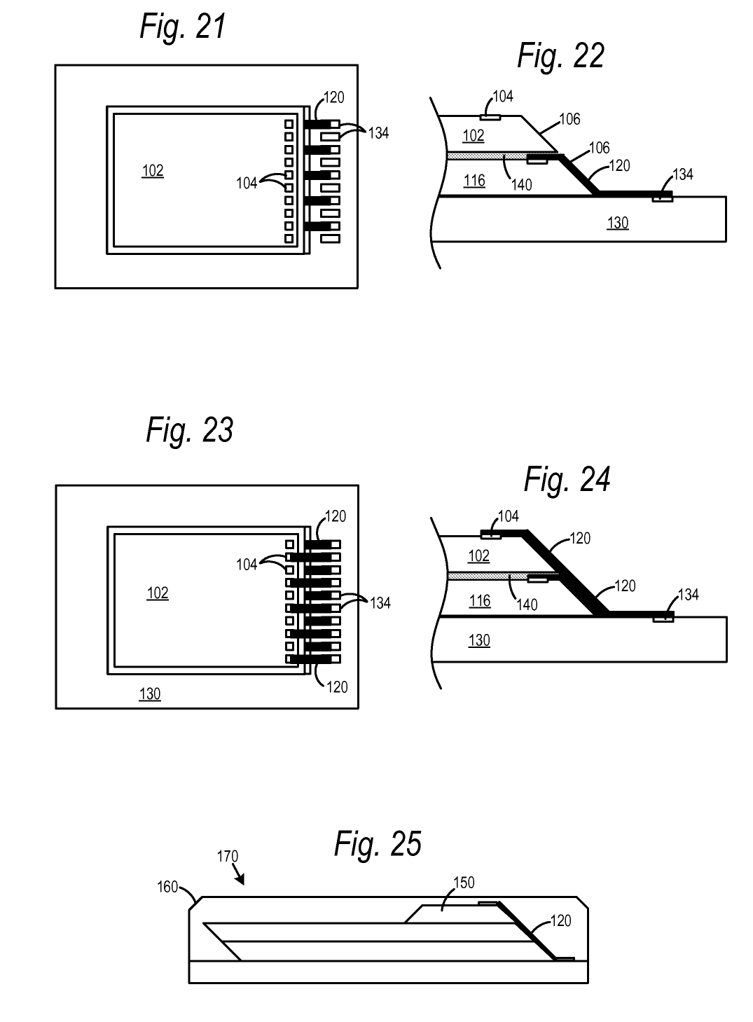

Referring now to FIGS. 21 and 22, a second semiconductor die 102 may then be mounted on top of semiconductor die 116. As best seen in FIG. 22, the die 102 may be offset from die 116 so that the positively sloped edges 106 of die 102 and 116 provide a substantially continuous positive slope. It is also understood that die 102 may be offset a greater amount than shown in FIG. 22 in alternative embodiments of the invention.

Referring now to FIGS. 23 and 24, a second set of electrical traces may then be deposited, coupling upper die 102 to substrate 130. In particular, conductive electrical traces 120 may be connected from bond pads 104 on die 102 down positively sloped edge 106 of die 102, down positively sloped edge 106 of die 116, and on to substrate 130 where traces 120 are coupled with bond pads 134. In this way, both die 102 and 116 may be mounted to substrate 130, in, for example, an offset configuration. While not all of the bond pads 104 are shown coupled in FIG. 23, it is understood that a greater number of bond pads 134 may be provided on substrate 130, and all of the bond pads 104 on die 102 may be coupled. In the embodiment of FIGS. 23 and 24, die 102 and 116 may both be flash memory die. A controller die, such as controller die 150 shown in FIG. 25, may further be included and coupled to the substrate 130 via positively sloped edges 106 and electrically conductive traces 120 as described above.

Referring now to the flowchart of FIG. 7 and the edge view of FIG. 25, once the semiconductor die in any of the above-described embodiments have been electrically coupled to the substrate, the die and at least portions of the substrate may be encapsulated in a mold compound 160 in step 212 to form a completed portable memory die package 170. The mold compound 160 may be a known epoxy such as for example available from Sumitomo Corp. and Nitto Denko Corp., both having headquarters in Japan. Thereafter, the finished package 170 may be subjected to electrical testing and burn-in in step 214, and optionally enclosed within a lid (not shown) in step 216.

The package 170 provides a low profile semiconductor package in which a plurality of semiconductor die may be electrically coupled to a substrate without having to provide wire bonds between each die and the substrate. In particular, forming electrical traces for example by digital printing directly on the surfaces of the die omits the vertical space required for wire bonding in conventional semiconductor packages. In addition to preventing the possibility of electrical short, omitting the wire bonds, and the accompanying space required for the wire bonds, allows a significant reduction in height and/or footprint of the package 170. This is especially true for semiconductor packages including large numbers of semiconductor die. The thickness of the package may be only nominally greater than the thickness of the substrate and the semiconductor die used in the package.

The embodiments described above include a single die mounted to a substrate, a controller die and memory die mounted to a substrate, and a controller die and a pair of memory die mounted to a substrate. Embodiments of the invention may alternatively include more than three total semiconductor die mounted on a substrate. The die may be stacked to form an SiP, MCM or other type of semiconductor package. Package 170 may be used in a standard flash memory enclosure, including for example an SD card, compact flash, smart media, mini SD card, MMC and xD card, a transflash or a memory stick. Other standard flash memory packages are also possible.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A method of forming a semiconductor die, comprising the steps of:
(a) forming a die bond pad on a surface of the semiconductor die; and
(b) singulating the semiconductor die from a wafer, with a cut along a first edge of the semiconductor die forming a sloped edge on the semiconductor die for receiving an electrically conductive trace.

2. A method as recited in claim 1, said step (b) of forming a sloped edge on the semiconductor die comprising the step of forming an angle of between 120 degrees and 150 degrees between the surface of the semiconductor die and the first sloped edge.

3. A method as recited in claim 1, further comprising the step (c) of singulating the semiconductor die from the wafer with a cut along a second edge of the semiconductor die opposite the first edge, said step (c) being made with a cut formed at an oblique angle to the surface of the semiconductor die to form a second sloped edge on the semiconductor die.

4. A method as recited in claim 3, said step (c) forming an angle of greater than 90 degrees between the surface and the second sloped edge.

5. A method as recited in claim 4, said step (c) forming an angle of between 120 degrees and 150 degrees between the surface and the second sloped edge.

6. A method as recited in claim 4, said step (c) forming a sloped edge on the semiconductor die for receiving an electrically conductive trace.

7. A method as recited in claim 3, said step (c) forming an angle of less than 90 degrees between the surface of the semiconductor die and the second sloped edge.

8. A method as recited in claim 7, said step (c) forming an angle of between 30 degrees and 60 degrees between the surface and the second sloped edge.

9. A method as recited in claim 1, further comprising the step (d) of singulating the semiconductor die from the wafer with cuts along third and fourth edges extending between the first and second edges.

10. A method as recited in claim 9, said step (d) of singulating the semiconductor die from the wafer with cuts along third and fourth edges comprising the step of cutting at least one of the third and fourth edges at an oblique angle to the semiconductor die to form a sloped edge on at least one of the third and fourth edges.

11. A method as recited in claim 1, said step (b) of singulating the semiconductor die from a wafer with a cut along a first edge of the semiconductor die comprising the step of cutting the first edge with a laser.

12. A method as recited in claim 1, said step (b) of singulating the semiconductor die from a wafer with a cut along a first edge of the semiconductor die comprising the step of cutting the first edge with a saw.

13. A method as recited in claim 1, said step (b) of singulating the semiconductor die from a wafer with a cut along a first edge of the semiconductor die comprising the step of cutting the first edge by chemically etching between the semiconductor die and a next adjacent semiconductor die.

14. A method of electrically coupling a semiconductor die to another component, comprising the steps of:
(a) forming a die bond pad on a surface of the semiconductor die;
(b) singulating the semiconductor die from a next adjacent semiconductor die with a cut formed at an oblique angle to the surface of the semiconductor die to form a sloped edge on the semiconductor die; and
(c) forming an electrically conductive trace on the semiconductor die coupled to the die bond pad formed in said step (a) and extending down the sloped edge of the semiconductor die formed in said step (b).

15. A method as recited in claim 14, said step (b) of singulating the semiconductor die from the next adjacent semiconductor comprising the step of singulating the semiconductor die with a laser.

16. A method as recited in claim 14, said step (b) of singulating the semiconductor die from the next adjacent semiconductor comprising the step of singulating the semiconductor die with a saw.

17. A method as recited in claim 14, said step (b) of singulating the semiconductor die from the next adjacent semiconductor comprising the step of singulating the semiconductor die by chemically etching a cut between the semiconductor die and the next adjacent semiconductor die.

18. A method as recited in claim 14, said step (b) of singulating the semiconductor die with a cut formed at an oblique angle to the surface of the semiconductor die comprising the step of forming the sloped edge at an angle of between 120 degrees and 150 degrees with respect to the surface of the semiconductor die.

19. A method as recited in claim 14, said step (b) of singulating the semiconductor die with a cut formed at an oblique angle to the surface of the semiconductor die comprising the step of forming the sloped edge at an angle of approximately 135 degrees with respect to the surface of the semiconductor die.

20. A method as recited in claim 14, said step (c) of forming an electrically conductive trace comprising the step of terminating the conductive trace on the other component.

21. A method as recited in claim 14, said step (c) of forming an electrically conductive trace comprising the steps of depositing a conductive material and etching the conductive material in a desired pattern to define the electrically conductive trace.

22. A method as recited in claim 14, said step (c) of forming an electrically conductive trace comprising the step of depositing an electrically conductive trace by a digital printing technique.

23. A method as recited in claim 22, said step of depositing an electrically conductive trace by a digital printing technique comprising the step of depositing discrete dots of a compound of a conductive material and a solvent.

24. A method as recited in claim 22, said step of depositing an electrically conductive trace by a digital printing technique comprising the step of depositing overlapping discrete dots to form a trace having a width of substantially a single discrete dot.

25. A method as recited in claim 22, said step of depositing an electrically conductive trace by a digital printing technique comprising the step of depositing overlapping discrete dots to form a trace having a width of a plurality of discrete dots.

26. A method of forming a semiconductor package, comprising the steps of:
(a) mounting a first semiconductor die atop a second component, the first semiconductor die having a sloped edge; and
(b) forming an electrically conductive trace from a first point on the surface of the first semiconductor die, along the sloped edge, to a second point on the surface of the second component to electrically couple the first semiconductor die and the second component.

27. A method as recited in claim 26, said step (a) of mounting a first semiconductor die atop a second component comprising the step of mounting the first semiconductor die atop a second semiconductor die.

28. A method as recited in claim 27, said step of mounting the first semiconductor die atop a second semiconductor die comprising the step of mounting a controller die atop a flash memory die.

29. A method as recited in claim 26, further comprising the steps of:
(c) mounting a second semiconductor die atop the first semiconductor die, the second semiconductor die having a sloped edge; and
(d) forming an electrically conductive trace from a first point on the surface of the second semiconductor die, along the sloped edge of the first and second semiconductor die, to a second point on the surface of the second component to electrically couple the second semiconductor die and the second component.

30. A method as recited in claim 26, further comprising the steps of:
(e) mounting a second semiconductor die atop the first semiconductor die, the second semiconductor die having a sloped edge; and
(f) forming an electrically conductive trace from a first point on the surface of the second semiconductor die, along the sloped edge of the first semiconductor die, to a second point on the surface of the first semiconductor die to electrically couple the second semiconductor die and the first semiconductor die.

31. A method as recited in claim 26, said step (b) of forming an electrically conductive trace comprising the steps of depositing a conductive material and etching the conductive material in a desired pattern to define the electrically conductive trace.

32. A method of forming a semiconductor package, comprising the steps of:
(a) mounting a first semiconductor die atop a second component, the first semiconductor die having a sloped edge; and
(b) depositing an electrically conductive trace by a digital print process from a first point on the surface of the first semiconductor die, along the sloped edge, to a second point on the surface of the second component to electrically couple the first semiconductor die and the second component.

33. A method as recited in claim 32, said step (a) of mounting a first semiconductor die atop a second component comprising the step of mounting the first semiconductor die atop a second semiconductor die.

34. A method as recited in claim 32, said step (a) of mounting a first semiconductor die atop a second component comprising the step of mounting a controller die atop a flash memory die.

35. A method as recited in claim 32, said step (a) of mounting a first semiconductor die atop a second component comprising the step of mounting the first semiconductor die atop a substrate.

36. A method as recited in claim 32, said step of depositing an electrically conductive trace by a digital print process comprising the step of depositing discrete dots of a compound of a conductive material and a solvent.

37. A method as recited in claim 36, said step of depositing an electrically conductive trace by depositing discrete dots of a compound comprising the step of forming the electrically conductive trace with a width substantially equal to a diameter of a deposited dot.

38. A method as recited in claim 36, said step of depositing an electrically conductive trace by depositing discrete dots of a compound comprising the step of forming the electrically conductive trace with a width substantially equal to a diameter of a plurality of deposited dots.

39. A method as recited in claim 32, further comprising the step (c) of encapsulating the semiconductor package in molding compound.

40. A semiconductor die, comprising:
a surface; and
four edges defining the surface, the four edges including first and second opposed edges, and third and fourth opposed edges extending between the first and second edges, at least one of the first, second, third and fourth edges being formed with a slope for receiving an electrically conductive trace.

41. A semiconductor die as recited in claim 40, wherein the first edge is sloped at an angle of greater than 90 degrees with respect to the surface of the semiconductor die for receiving an electrically conductive trace.

42. A semiconductor die as recited in claim 40, wherein the first edge is sloped at an angle of between 120 degrees and 150 degrees with respect to the surface of the semiconductor die for receiving an electrically conductive trace.

43. A semiconductor die as recited in claim 40, wherein the second edge is sloped at an angle of greater than 90 degrees with respect to the surface of the semiconductor die for receiving an electrically conductive trace.

44. A semiconductor die as recited in claim 40, wherein the second edge is sloped at an angle of less than 90 degrees with respect to the surface of the semiconductor die.

45. A semiconductor package:
a first semiconductor die, including:
a surface, and
four edges defining the surface, the four edges including first and second opposed edges, and third and fourth opposed edges extending between the first and second edges, at least one of the first, second, third and fourth edges being formed with a slope for receiving an electrically conductive trace;
a second component to which the first semiconductor die is coupled; and
at least one electrically conductive trace formed on the surface, the at least one sloped edge and the second component, the at least one electrically conductive trace electrically coupling the first semiconductor die and the second component.

46. A semiconductor package as recited in claim 45, further comprising an electrical insulator on the at least one sloped edge, in between the at least one sloped edge and the at least one electrically conductive trace.

47. A semiconductor package as recited in claim 45, wherein an electrically conductive trace of the at least one electrically conductive traces electrically couples a bond pad on the first semiconductor die to a bond pad on the second component.

48. A semiconductor package as recited in claim 45, wherein the first semiconductor die is a controller die and the second component is a flash memory die.

49. A semiconductor package as recited in claim 45, wherein the first semiconductor die is a flash memory die and the second component is a substrate.

50. A semiconductor package as recited in claim 45, wherein the first semiconductor die is a controller die and the second component is a substrate.

51. A semiconductor package as recited in claim 45, wherein two or more edges of the first semiconductor die are sloped and include a conductive trace.

52. A semiconductor package as recited in claim 45, further comprising molding compound for encapsulating the semiconductor package.

53. A semiconductor package:
a first semiconductor die, including:
a surface including a first bond pad, and
an edge formed with a slope;
a second component, to which the first semiconductor die is coupled, including a second bond pad; and
a plurality of overlapping conductive dots, digitally printed on the surface of the first semiconductor die, the sloped edge of the first semiconductor die and the second component, electrically coupling the first bond pad to the second bond pad.

54. A semiconductor package as recited in claim 53, wherein dots of the plurality of overlapping conductive dots have a diameter of between 5 microns and 30 microns.

55. A semiconductor package as recited in claim 53, wherein dots of the plurality of overlapping conductive dots have a diameter of between 10 microns and 20 microns.

56. A semiconductor package as recited in claim 53, further comprising an electrical insulator on the sloped edge on which a group of the plurality of overlapping conductive dots are deposited.

57. A semiconductor package as recited in claim 53, wherein the first semiconductor die is a controller die and the second component is a flash memory die.

58. A semiconductor package as recited in claim 53, wherein the first semiconductor die is a flash memory die and the second component is a substrate.

59. A semiconductor package as recited in claim 53, wherein the first semiconductor die is a controller die and the second component is a substrate.

60. A semiconductor package as recited in claim 53, further comprising molding compound for encapsulating the semiconductor package.

61. A semiconductor package as recited in claim 53, wherein the semiconductor package is one of a Compact Flash, a Smart Media, an SD Card, a Mini SD Card, an MMC, an xD Card, a Transflash or a Memory Stick.
